(19) United States
(12) Patent Application Publication
(10) Pub. No.: US 2014/0360549 A1
(43) Pub. Date: Dec. 11, 2014

(54) Thermoelectric Module and Method of Making Same

(71) Applicant: GMZ Energy, Inc., Waltham, MA (US)

(72) Inventors: Xiaowei Wang, Chestnut Hill, MA (US); Johnathan D'Angelo, Somerville, MA (US)

(21) Appl. No.: 14/299,031

(22) Filed: Jun. 9, 2014

Related U.S. Application Data
(60) Provisional application No. 61/833,169, filed on Jun. 10, 2013.

(51) Int. Cl. H01L 35/32; H01L 35/34

(52) U.S. Cl. CPC H01L 35/325; H01L 35/34
USPC 136/211; 438/54; 136/201

(57) ABSTRACT

Thermoelectric modules and methods of making thermoelectric modules that include a plurality of row couples each comprising interconnected pairs of n-type and p-type thermoelectric material legs between a first bonding area and a second bonding area, a first connector bonded to each of the first bonding areas of the plurality of row couples, and a second connector bonded to each of the second bonding areas of the plurality of row couples, wherein the first and second connectors provide mechanical support for and electrical connection between the plurality of row couples. The first and second connectors may be connector members having a patterned conductive surface to define a circuit configuration for the module.

### CROSS-REFERENCE TO RELATED APPLICATION

This application claims the benefit of priority to U.S. Provisional Application No. 61/833,169, filed on Jun. 10, 2013, the entire contents of which are incorporated herein by reference.

### BACKGROUND

Devices for cooling and power generation based on thermoelectric effects are known in the art. Solid-state devices that employ the Seebeck effect or Peltier effect for power generation and heat pumping are known. For power generation, for example, a thermoelectric converter relies on the Seebeck effect to convert temperature differences into electricity. A thermoelectric generator (TEG) module includes a first (hot) side, a second (cold) side, and a plurality of thermoelectric converters disposed there between (e.g., pairs of p-type and n-type legs of thermoelectric material). The TEG module may include suitable electrical interconnections between each of the thermoelectric converters, as well as electrical leads for extracting electrical energy generated by the module.

### SUMMARY

Embodiments include a thermoelectric module that includes a plurality of row couples each comprising interconnected pairs of n-type and p-type thermoelectric material legs between a first bonding area and a second bonding area, a first connector bonded to each of the first bonding areas of the plurality of row couples, and a second connector bonded to each of the second bonding areas of the plurality of row couples, wherein the first and second connectors provide mechanical support for and electrical connection between the plurality of row couples. In embodiments, the first and/or second connector may be a connector member having a patterned conductive surface that defines a circuit configuration for the module.

Further embodiments include methods of fabricating a thermoelectric module that include providing a plurality of row couples each comprising interconnected pairs of n-type and p-type thermoelectric material legs between a first bonding area and a second bonding area, bonding a first connector to each of the first bonding areas of the plurality of row couples, and bonding a second connector to each of the second bonding areas of the plurality of row couples, wherein the first and second connectors provide mechanical support for and electrical connection between the plurality of row couples.

### BRIEF DESCRIPTION OF THE DRAWINGS

The accompanying drawings, which are incorporated herein and constitute part of this specification, illustrate exemplary embodiments of the invention, and together with the general description given above and the detailed description given below, serve to explain the features of the invention.

FIG. 1 is a side view of a row couple of thermoelectric material legs electrically connected in series by metal connectors.

FIG. 2A is a perspective view of a thermoelectric generator module that includes a plurality of row couples electrically and mechanically connected by connector members having a conductive interfacing surface.

FIG. 2B is a partial perspective view of an alternative embodiment of a thermoelectric generator module in which a multi-component connector member is attached to top and bottom surfaces of the row couples.

FIGS. 3A-D schematically illustrate top views of embodiments of circuit configurations for a thermoelectric generator module that includes row couples connected by connector members.

### DETAILED DESCRIPTION

The various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims.

Multiple methods exist for generating electricity from heat energy. Various embodiments may include thermoelectric conversion elements. Thermoelectric conversion relies on the Seebeck effect to convert temperature differences into electricity. Thermoelectric converters operate more efficiently under greater temperature differences.

For example, solar thermoelectric generators include solar radiation absorbers that transfer solar energy to the high-temperature sides of thermoelectric converters such that a temperature differential is achieved across the thermoelectric converters that may be converted to electricity. Examples of this type of device are disclosed in U.S. Published Patent Application No. 2012/0160290, published on Jun. 28, 2012, the entire contents of which are incorporated herein by reference for all purposes. In addition to solar energy, various other heat sources may be used to provide a temperature difference across thermoelectric conversion elements, such as, for example, a hot fluid flow stream, boiler heat, automobile exhaust, industrial waste heat, etc. A heat exchanger may be used to transfer heat from the flow stream to a first side (i.e., the “hot” side) of the thermoelectric conversion elements.

In many of these systems, the temperature at the “hot” side of the thermoelectric element may be relatively high, such as 400° C. or more (e.g., ≧600° C., such as 600-800° C.). Furthermore, the temperature differential between the “hot” and “cold” sides of the elements may also be quite large, such as up to about 500° C. or more. At these temperatures and temperature differentials, thermal stress is a key challenge for thermoelectric generator reliability.

Various embodiments include thermoelectric modules and methods of fabricating thermoelectric modules. The module design of the various embodiments may provide a cost-effective, universal approach that can be used in any thermoelectric material-based system, and may be readily scaled up or down to any suitable module size or configuration.

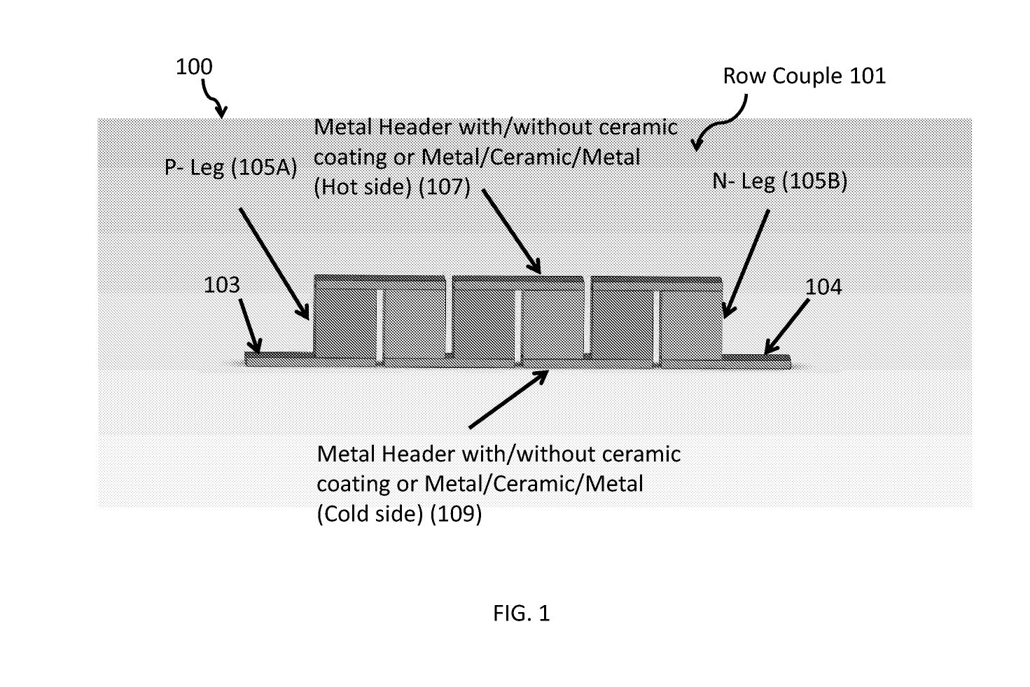

FIG. 1 is a side view of a portion of a thermoelectric module 100 according to one embodiment. The module 100 includes a plurality of pairs of p-type thermoelectric material legs 105A and n-type thermoelectric material legs 105B. Each pair of legs 105A, 105B are thermally and electrically coupled at a first (e.g., hot) end, e.g., to form a junction such as a pn junction or p-metal-n junction. The junction can be a header 107 made of an electrically conductive material, such as a metal. Electrical connectors 109 (which may be metal connectors that are the same as or different than the headers 107) may be connected to the second (cold) ends of the thermoelectric legs 105A, 105B, and may be laterally offset from the header connector 107 such that for each pair of n-type and p-type legs, one leg 105A (e.g., a p-type leg) contacts a first connector 109, and the other leg 1058 (e.g., an n-type leg) contacts a second connector 109. Thus, any arbitrary number of thermoelectric material leg pairs may be electrically connected in series by respective (hot side) headers 107 and (cold side) connectors 109, as shown in FIG. 1. A set of interconnected thermoelectric leg pairs such as shown in FIG. 1 may be referred to as a “row couple” 101, and a module 100 may be formed of a plurality of row couples 101. The terminal electrical connectors 109 on opposing ends of the row couple 101 may include first and second bonding regions 103, 104, respectively, that enable the row couples 101 to be connected to other row couples and/or to electrical leads for extracting electrical energy from the module 100.

In embodiments, the metal headers 107 may include an electrically conductive material (e.g., metal) on a first (e.g., bottom) surface of the header 107 that faces the thermoelectric legs 105A, 105B, and an electrically insulating material on a second surface of the header 107 (e.g., the top surface of the header in FIG. 1), opposite the legs 105A, 105B to provide electrical isolation between the row couple 101 and the module 100 packaging, which may include a metal cover (not shown) mounted over the row couples 101. In embodiments, the headers 107 may comprise a metal material having a coating of a non-conductive ceramic material over a surface of the header 107. The header 107 may have layered structure, such as a metal/ceramic/metal sandwich structure. Similarly, the connectors 109 on the “cold” sides of the legs 105A, 105B may also include an electrically insulating material (e.g., a ceramic coating) over the bottom surface of the connectors 109 to electrically isolate the row couple 101 on its “cold” side. The connector 109 may also have a metal/ceramic/metal sandwich structure.

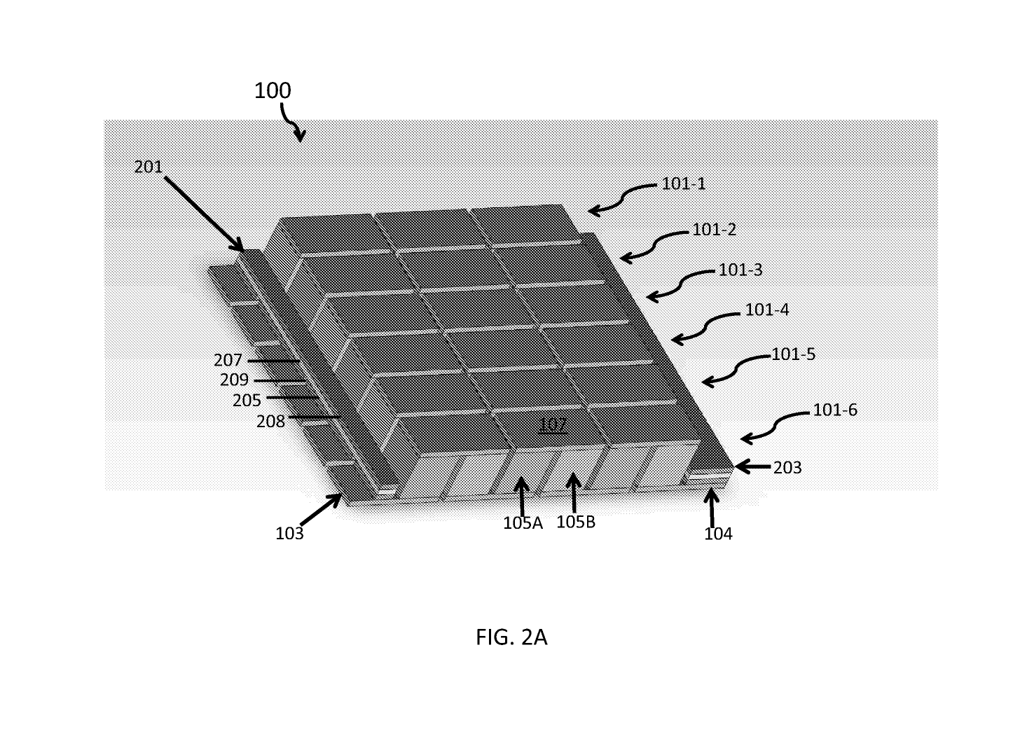

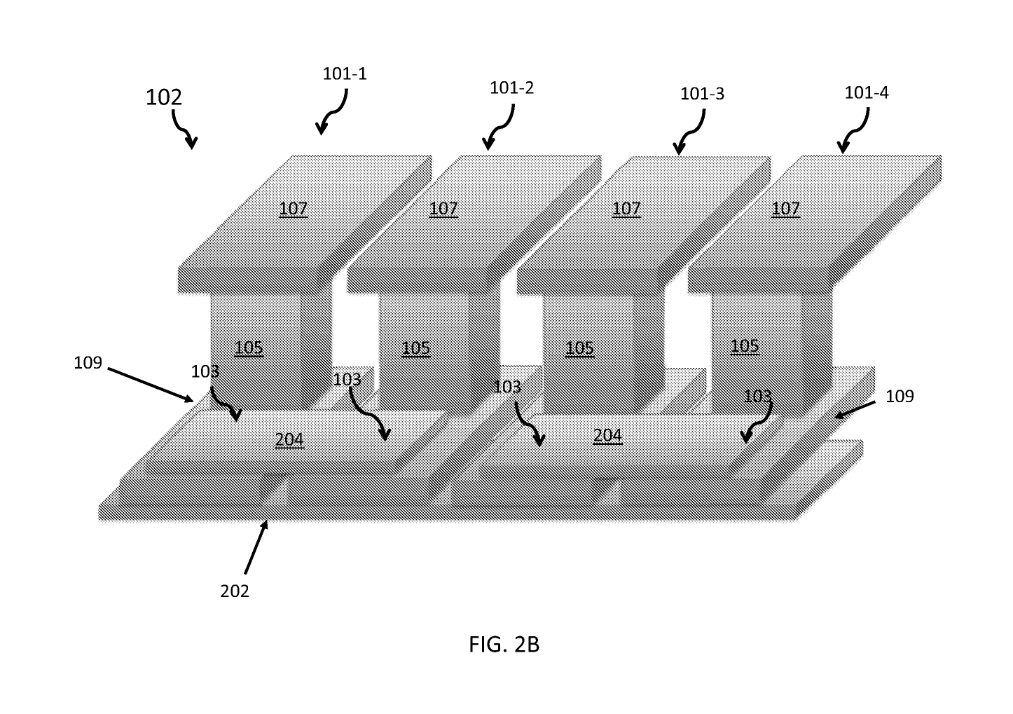

FIG. 2A schematically illustrates a thermoelectric module 100 comprising a plurality of row couples 101-1, 101-2, 101-3, 101-4, 101-5, 101-6 aligned parallel to one another. For ease of illustration, the module 100 is shown without a cover over the “hot” side of the module 100. The first bonding regions 103 of each row couple 101-1, 101-2, . . . 101-6 are adjacent to one another on a first end of the module 100, and the second bonding regions 104 of each row couple 101-1, 101-2, . . . 101-6 are adjacent to one another on the opposite end of the module 100. A first connector member 201 is provided across each of the first bonding regions 103 and a second connector member 203 is provided across each of the second bonding regions 104. While six row couples are shown, any number (e.g., 2-100) can be used.

In embodiments, the first and second connector members 201, 203 may comprise rigid or semi-rigid members made of one or more structural materials that provide mechanical support and electrical interconnection for the respective row couples 101-1, 101-2, . . . 101-6. The first and second connector members 201, 203 may be bonded to the bonding regions 103, 104 using any suitable technique, such as via brazing, soldering, welding, solid state diffusion, or by a suitable adhesive material. The connector members 201, 203 may provide a mechanical frame that provides structural integrity and maintains a desired spacing between the row couples 101-1, 101-2, . . . 101-6 of the thermoelectric module 100.

In an alternative embodiment, the first and/or second connector members 201, 203 can comprise multiple element members. FIG. 2B is a partial perspective view of an alternative embodiment of a thermoelectric module 102 using a multi-component connector members. In this embodiment, a first component 202 is bonded to underside of the bonding region 103 of each row couple 101-1, 101-2, 101-3, 101-4 (i.e., to the surface of the connector 109 opposite the thermoelectric elements 105). The first component 202 may provide mechanical support for the row couples 101-1, 101-2, 101-3, 101-4, and may be electrically isolated from the bonding regions 103 (i.e., such that the first component 202 does not electrically connect the respective row couples 101-1, 102-2, 103-3, 101-4). Although only four row couples are shown FIG. 2B, the first component 202 may be used to connect any number of row couples. The first component 202 may be or may include a metal strip, and may be electrically isolated from the row couples by a layer or coating of insulating material, such as an intermediate ceramic layer located between the metal strip and the bonding region(s) 103 of the row couples 101-1, 102-2, 103-3, 101-4. In the embodiment of FIG. 2B, for example, an intermediate ceramic layer (not illustrated) may be located over the top surface of the first component 202 and/or under the bottom surface of the connectors 109. In embodiments, the connectors 109 may have a metal/ceramic/metal sandwich structure to provide electrical isolation between their top and bottom surfaces, and thus isolate the first component 202 from the bonding regions 103. The first component 202 of the connector member may also have a metal/ceramic/metal sandwich structure. A second component 204 of the connector member may include one or more electrically conductive strips that are bonded to the top surface of the bonding region 103 to provide electrical interconnection between the respective row couples 101-1, 102-2, 103-3, 101-4 in a desired circuit arrangement. Each second component 204 may have an electrically conductive surface bonded to the bonding regions 103 of any desired number of row couples to provide electrical connection between the row couples. The second component(s) 204 may be or may include a metal strip, and may have a metal/ceramic/metal sandwich structure.

Each of the connector members 201, 203 may comprise an electrically conductive material 205, such as a metal, over at least a portion of the surfaces of the connector members 201, 203 that interface with the respective bonding regions 103, 104 of the row couples 101-1, 101-2, . . . 101-6. The electrically conductive material 205 may be continuous over the entire interfacing surface of the connector member 201, 203, or in some embodiments, may be patterned to include non-continuous regions of electrically conductive material 205 separated by non-conductive regions or gaps 209, as shown in FIG. 2A.

In embodiments, the connector members 201, 203 may include a first layer 207 of non-conductive material and a second layer 205 of conductive material under the first layer 207. A third layer 208 is shown over the second layer 205, and may be, for example, an electrically insulating or conductive layer. In other embodiments, layer 208 may be omitted. Portions of the second layer 205 may be removed to provide a desired pattern of conductive regions separated by non-conductive gaps 209. The connector members 201, 203 may then be bonded to the respective first and second bonding regions 103, 104 of the row couples, with the conductive second layer 205 electrically connected to the bonding regions 103, 104. The non-conductive gaps 209 may be located between select row couples 101-1, 101-2, . . . 101-6 to define a circuit pattern through the row couples 101-1, 101-2, . . . 101-6. Alternatively, a continuous conductive second layer 205 may be bonded to the bonding regions 103, 104, and portions of the second layer 205 may be removed between select row couples 101-1, 101-2, . . . 101-6 to define the circuit pattern. Any conductor (e.g., metal or metal alloy, such as copper, nickel, titanium, etc., or combinations or alloys of the same, may be used for the electrically conductive material 205 of connector members 201, 203.

In one embodiment, the connector members 201, 203 may be formed using a direct bonded copper (DBC) technique. Direct bonded copper (DBC) substrates include a ceramic tile (e.g., alumina, aluminum nitride, beryllium oxide, etc.) with a sheet of copper bonded to one or both sides by a high-temperature oxidation process (e.g., heating the copper and substrate in controlled atmosphere of nitrogen and about 30 ppm oxygen to form a copper-oxygen eutectic which bonds to both the copper layer and the oxide(s) of the substrate layer). DBC substrates are often used in power modules due to their high thermal conductivity. The copper surface layer may be patterned prior to firing and/or portions of the copper layer may be removed after firing (e.g., etched using printed circuit board technology) to form the patterned conductive layer 205 and non-conductive gaps 209. The copper surface layer may be formed into any desired pattern for electrically connecting a plurality of row couples 101-1, 101-2, . . . 101-6 in a series and/or parallel circuit configuration. The headers 107 and connectors 109 that connect the thermoelectric legs may also be formed using a DBC structure (e.g., to provide a metal/ceramic/metal sandwich structure).

In some embodiments, a DBC substrate may be formed and optionally patterned to define a circuit pattern in the copper surface layer, and the DBC substrate may then be diced into strips to form the individual connector members 201, 203. The length and width of the strips may be variable depending on the size of the module 100 and bonding regions 103, 104. As shown in FIG. 2A, for example, the length of connector members 201, 203 is sufficient to connect the six row couples, 101-1, 101-2, . . . 101-6, and can be made longer or shorter to accommodate a module 100 having more or less row couples. In this embodiment, the width of connector member 203 is sufficient to substantially completely cover bonding regions 104 (while leaving a small gap between the connector member 203 and the adjacent thermoelectric material legs 105B to prevent the legs from shorting to the connector member 203). This design may improve the mechanical stability of the module 100. On the opposite side of the module 100 in this embodiment, the width of the connector member 201 is relatively narrower to leave a portion of the bonding regions 103 exposed. Conductive leads (not shown) may be bonded or otherwise secured to the exposed portions of bonding regions 103 to provide an external electrical connection to the module 100. Other means for providing an external electrical connection to the module 100 may be utilized. For example, one or more through-holes or vias may be formed through the connector member(s) 201, 203 and used to electrically connect the respective bonding region(s) 103, 104 to an external lead, and/or portions of the connector member(s) 201, 203 may extend out beyond the bonding region(s) 103, 104, and conductive leads may be attached to these portions of the connector member(s) 201, 203. The first and/or second components 202, 204 of the multi-component connector member as shown in FIG. 2B may also use strips of a DBC structure.

Mechanically and electrically connecting a plurality of discrete row couples 101 using connector members 201, 203 may provide a thermoelectric module 100 having an improved thermal mechanical arrangement relative to conventional designs. In a typical design for a thermoelectric module, one or both of the hot and cold sides of the module is anchored to a supporting substrate, such as a ceramic board. In such a design, thermal stress due to large temperature gradients and coefficient of thermal expansion (CTE) mismatches between the materials can damage or even break the module especially at high temperature. In the device of FIG. 2A, the row couples 101 are mechanically supported by connector members 201, 203 and the segmental metal headers/connectors 107, 109 on both the hot and cold sides of the module which minimizes the stress due to thermal gradient and CTE mismatch between the header/connector and the thermoelectric material. In the embodiment of FIG. 2A, for example, the connectors 109 on the cold side of the module are not bonded to a common supporting substrate. Thus, the various components of the module 100, including the cold side connectors 109, the thermoelectric legs 105A, 105B, the hot side headers 107 and/or the row couples 101 themselves may have more freedom of movement relative to one another during varying thermal conditions, which may improve the useful life of the device.

The thermoelectric modules 100 of the various embodiments may also provide a relatively high filling factor, which is defined as the ratio of the total cross-sectional area of all thermoelectric material legs 105A, 105B in the module 100 to the total area of the module 100 through a cross-section of the module 100 intersecting each of the legs 105A, 105B (e.g., cross-section parallel to the plane of headers 107). In various embodiments, the filling factor of the module 100 may be 80% or more, such as 85-100% (e.g., ≧90%, such as 95-100%).

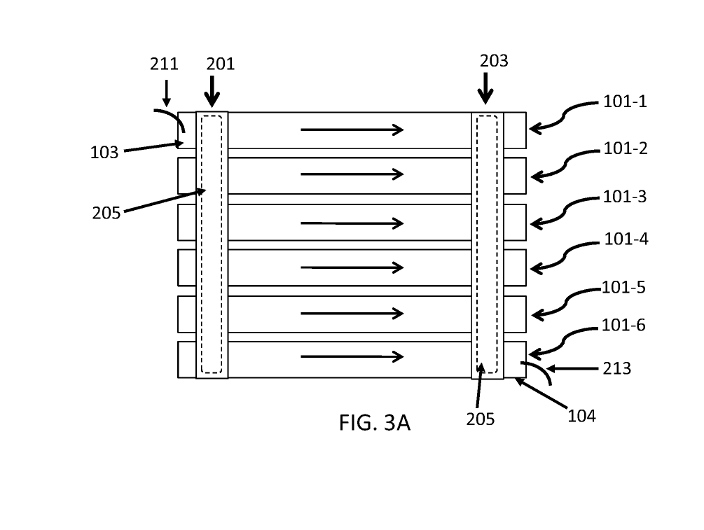

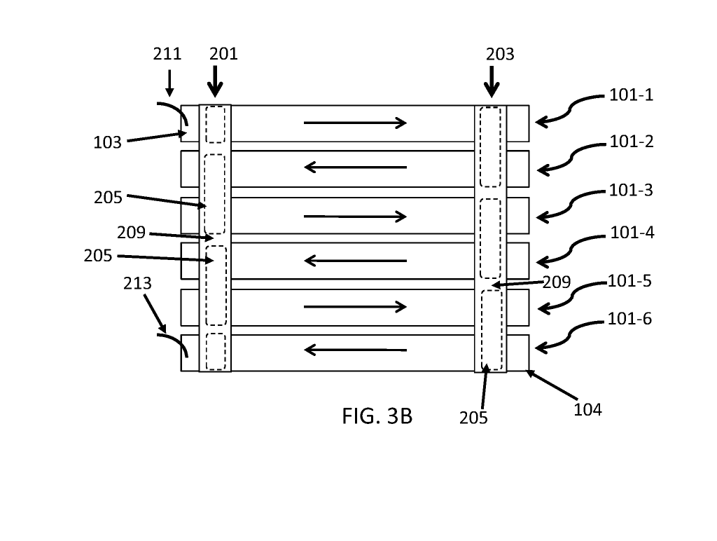

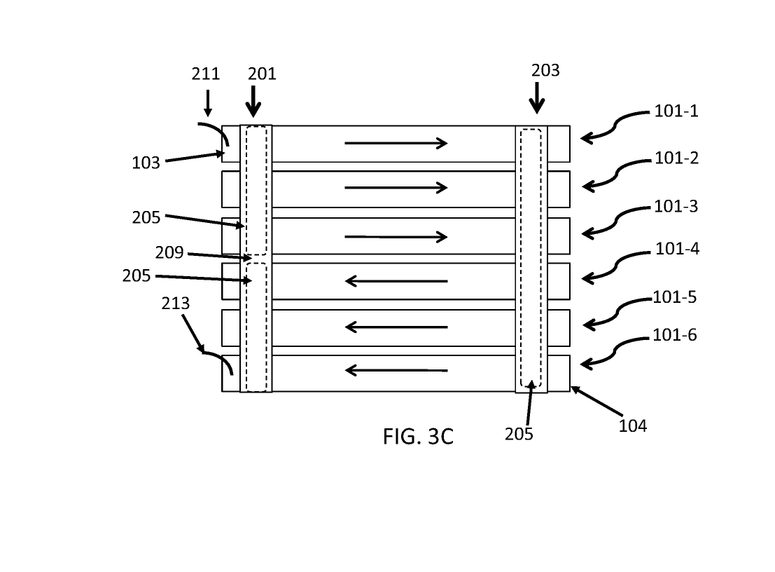

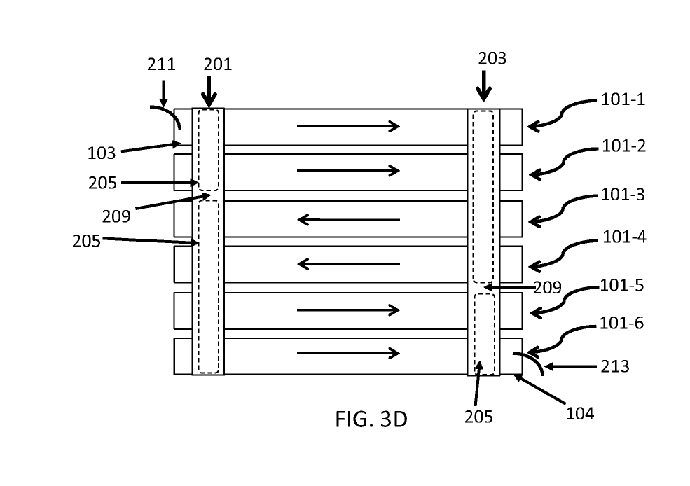

As discussed above, the interfacing conductive surface layer 205 of the connector members 201, 203 may be formed into any desired pattern for electrically connecting the plurality of row couples 101-1, 101-2, . . . 101-6 in a series and/or parallel circuit configuration. Various examples of circuit configurations for a thermoelectric module 100 are schematically illustrated in FIGS. 3A-D. For ease of illustration, the module 100 is shown in an overhead (e.g., top) plan view with each of the row couples 101-1, 101-2, . . . 101-6 being depicted schematically as a rectangle extending between a first bonding region 103 and a second bonding region 104. It will be understood that the row couples 101-1, 101-2, . . . 101-6 may be configured as shown in FIGS. 1 and 2. Each of the connector members 201, 203 extends along the respective first and second bonding regions 103, 104 transverse to the row couples 101-1, 101-2, . . . 101-6. The conductive surface layer 205 of each connector member 201, 203 that interfaces with the respective first and second bonding regions 103, 104 of the row couples 101-1, 101-2, . . . 101-6 is indicated by dashed lines in FIGS. 3A-D. The figures also illustrate first and second conductive leads 211, 213 connected to the module 100. Arrows illustrate the direction of current flow through each row couple 101-1, 101-2, . . . 101-6 between the first conductive lead 211 and the second conductive lead 213.

FIG. 3A illustrates a first embodiment in which the conductive surface layer 205 of each connector member 201, 203 is continuous over the length of the connector members 201, 203. In this embodiment, the conductive surface layer 205 need not be patterned, and the entire connector members 201, 203 or portions thereof contacting regions 103, 104 may be formed of conductive material (e.g., metal). In this configuration, all of the row couples 101-1, 101-2, . . . 101-6 are electrically connected in parallel, as indicated by the arrows in FIG. 3A.

FIG. 3B illustrates a second embodiment in which the row couples 101-1, 101-2, . . . 101-6 are electrically connected in a series circuit configuration. In this embodiment, the conductive surface layers 205 of the connector members 201, 203 are not continuous. The conductive surface layers 205 may be patterned to provide discrete conductive regions separated by non-conductive gaps 209, as shown in FIG. 3B. Current flows in series through each of the row couples 101-1, 101-2, . . . 101-6 between first lead 211 and second lead 213, as indicated by the arrows in FIG. 3B.

FIG. 3C illustrates a third embodiment in which the row couples 101-1, 101-2, . . . 101-6 are connected in a combination of parallel and series configuration. In this embodiment, two groups of parallel-connected row couples (e.g., 101-1, -2, -3 and 101-4, -5, -6) are connected in series. FIG. 3D illustrates yet another embodiment in which adjacent pairs of row couples (e.g., 101-1, -2 and 101-3, -4 and 101-5, -6) are connected in parallel, and the respective pairs of row couples are connected in series. Various other configurations are possible, as will be understood by one skilled in the art.

Although the embodiments have been described in terms of a thermoelectric generator module 100 for converting temperature differences into electricity using the Seebeck effect, the various embodiments may also be used for a heat pumping device that uses the Peltier effect to convert electrical power to a temperature differential across a hot side and a cold side of the module 100.

In various embodiments, the thermoelectric material legs 105A, 105B may be made from a variety of bulk materials and/or nanostructures. The thermoelectric materials can comprise, but are not limited to, one of: half-Heuslers, Bi₂Te₃, Bi₂Te₃₋ₓSeₓ (n-type)/BiₓSe₂₋ₓTe₃ (p-type), SiGe (e.g., Si₈₀Ge₂₀₎, PbTe, skutterudites, Zn₃Sb₄, AgPbₘSbTe₂₊ₘ, Bi₂Te₃/Sb₂Te₃ quantum dot superlattices (QDSLs), PbTe/PbSeTe QDSLs, PbAgTe, and combinations thereof. The materials may comprise compacted nanoparticles or nanoparticles embedded in a bulk matrix material. For example, see U.S. patent application Ser. No. 11/949,353 filed Dec. 3, 2007, which is incorporated herein by reference for all purposes, for a description of exemplary materials.

In preferred embodiments, the thermoelectric elements comprise half-Heusler materials. Suitable half-Heusler materials and methods of fabricating half-Heusler thermoelectric elements are described in U.S. patent application Ser. No. 13/330,216 filed Dec. 19, 2011 and Ser. No. 13/719,96 filed Dec. 19, 2012, the entire contents of both of which are incorporated herein by reference for all purposes. Half-Heuslers (HHs) are intermetallic compounds which have great potential as high temperature thermoelectric materials for power generation. HHs are complex compounds: MCoSb (p-type) and MNiSn (n-type), where M can be Ti or Zr or Hf or combination of two or three of the elements. Sn and Sb can be substituted by Sn/Sb; Co and Ni by Ir and Pd. They form in cubic crystal structure with a F4/3m (No. 216) space group. These phases are semiconductors with 18 valence electron count (VEC) per unit cell and a narrow energy gap. The Fermi level is slightly above the top of the valence band. The HH phases have a fairly decent Seebeck coefficient with moderate electrical conductivity. The performance of thermoelectric materials depends on ZT, defined by ZT=(S²σ/κ)T, where σ is the electrical conductivity, S the Seebeck coefficient, κ the thermal conductivity, and T the absolute temperature. Half-Heusler compounds may be good thermoelectric materials due to their high power factor (S²σ).

The dimensionless thermoelectric figure-of-merit (ZT) of conventional HHs is lower than that of many other state-of-the-art thermoelectric materials. Recently, enhancements in the dimensionless thermoelectric figure-of-merit (ZT) of n-type half-Heusler materials using a nanocomposite approach has been achieved. A peak ZT of 1.0 was achieved at 600-700° C., which is about 25% higher than the previously reported highest value. The materials may be made by ball milling ingots of composition Hf_{0.75}Zr_{0.25}NiSn_{0.99}Sb_{0.1} into nanopowders and hot pressing (e.g., DC hot pressing or without the application of current) the powders into dense bulk samples. The ingots may be formed by arc melting the constituent elements. The ZT enhancement mainly comes from reduction of thermal conductivity due to increased phonon scattering at grain boundaries and crystal defects, and optimization of antimony doping.

By using a nanocomposite half-Heusler material, a greater than 35% ZT improvement from 0.5 to 0.8 in p-type half-Heusler compounds at temperatures above 400° C. has been achieved. Additionally, a 25% improvement in peak ZT, from 0.8 to 1.0 at temperatures above 400° C., in n-type half-Heusler compounds by the same nanocomposite approach has been achieved. The ZT enhancement is not only due to the reduction in the thermal conductivity but also an increase in the power factor. These nanostructured samples may be prepared, for example, by hot pressing a ball milled nanopowder from ingots which are initially made by an arc melting process. The hot pressed, dense bulk samples may be nanostructured with grains having a mean grain size less than 300 nm in which at least 90% of the grains are less than 500 nm in size. In some cases, the grains have a mean size in a range of 10-300 nm, such as a mean size of around 200 nm. Typically, the grains have random orientations. Further, many grains may include 10-50 nm size (e.g., diameter or width) nanodot inclusions within the grains.

Embodiments of the half-Heusler materials may include varying amounts of Hf, Zr, Ti, Co, Ni, Sb, Sn depending on whether the material is n-type or p-type. Other alloying elements such as Pb may also be added. Example p-type materials include, but are not limited to, Co containing and Sb rich/Sn poor Hf_{0.5}Zr_{0.5}CoSb_{0.8}Sn_{0.2}, Hf_{0.3}Zr_{0.7}CoSb_{0.7}Sn_{0.3}, Hf_{0.5}Zr_{0.5}CoSb_{0.8}Sn_{0.2}+1% Pb, Hf_{0.5}Ti_{0.5}CoSb_{0.8}Sn_{0.2}, and Hf_{0.5}Ti_{0.5}CoSb_{0.6}Sn_{0.4}. Example n-type materials include, but are not limited to, Ni containing and Sn rich/Sb poor Hf_{0.75}Zr_{0.25}NiSn_{0.975}Sb_{0.025}, Hf_{0.25}Zr_{0.25}Ti_{0.5}NiSn_{0.994}Sb_{0.006}, Hf_{0.25}Zr_{0.25}NiSn_{0.99}Sb_{0.01}(Ti_{0.30}Hf_{0.35}Zr_{0.35})Ni(Sn_{0.994}Sb_{0.006}), Hf_{0.25}Zr_{0.25}Ti_{0.5}NiSn_{0.99}Sb_{0.01}, Hf_{0.5}Zr_{0.25}Ti_{0.25}NiSn_{0.99}Sb_{0.01} and (Hf,Zr)_{0.5}Ti_{0.5}NiSn_{0.998}Sb_{0.002}.

The ingot may be made by arc melting individual elements of the thermoelectric material in the appropriate ratio to form the desired thermoelectric material. Preferably, the individual elements are 99.9% pure. More preferably, the individual elements are 99.99% pure. In some cases, two or more of the individual elements may first be combined into an alloy or compound and the alloy or compound used as one of the starting materials in the arc melting process. Ball milling may result in a nanopowder with nanometer size particles that have a mean size less than 100 nm in which at least 90% of the particles are less than 250 nm in size. In one example, the nanometer size particles have a mean particle size in a range of 5-100 nm.

It has been discovered that the figure of merit of thermoelectric materials improves as the grain size in the thermoelectric material decreases. In one example of a method for fabricating thermoelectric materials, thermoelectric materials with nanometer scale (less than 1 micron) grains are produced, i.e., 95%, such as 100% of the grains have a grain size less than 1 micron. Preferably, the nanometer scale mean grain size is in a range of 10-300 nm. This method may be used to fabricate any thermoelectric material and includes making half-Heusler materials with nanometer scale grains. The method may be used to make both p-type and n-type half-Heusler materials. In one example, the half-Heusler material is n-type and has the formula Hf_{1+δ-x-y}ZrₓTi_{y}NiSn_{1+δ-z}Sb_{z}, where 0≦x≦1.0, 0≦y≦1.0, 0≦z≦1.0, and −0.1≦δ≦0.1 (to allow for slightly non-stoichiometric material), such as Hf_{1-x-y}ZrₓTi_{y}NiSn_{1-z}Sb_{z}, where 0≦x≦1.0, 0≦y≦1.0, and 0≦z≦1.0 when δ=0 (i.e., for the stoichiometric material). In another example, the half-Heusler is a p-type material and has the formula Hf_{1+δ-x-y}ZrₓTi_{y}CoSb_{1+ε-z}Sn_{z}, where 0≦x≦1.0, 0≦y≦1.0, 0≦z≦1.0, and −0.1≦δ≦0 (to allow for slightly non-stoichiometric material), such as Hf_{1-x-y}ZrₓTi_{y}CoSb_{1-z}Sn_{z}, where 0≦x≦1.0, 0≦y≦1.0, and 0≦z≦1.0 when δ=0 (i.e., for the stoichiometric material).

The preceding description of the disclosed aspects is provided to enable any person skilled in the art to make or use the present invention. Various modifications to these aspects will be readily apparent to those skilled in the art, and the generic principles defined herein may be applied to other aspects without departing from the scope of the invention. Thus, the present invention is not intended to be limited to the aspects shown herein but is to be accorded the widest scope consistent with the principles and novel features disclosed herein.

What is claimed is:

1. A thermoelectric module, comprising:
a plurality of row couples each comprising interconnected pairs of n-type and p-type thermoelectric material legs between a first bonding area and a second bonding area;
a first connector bonded to each of the first bonding areas of the plurality of row couples; and
a second connector bonded to each of the second bonding areas of the plurality of row couples, wherein the first and second connectors provide mechanical support for and electrical connection between the plurality of row couples.

2. The thermoelectric module of claim 1, wherein each of the first and second connectors comprises a connector member having an electrically conductive surface layer bonded to the respective first and second bonding areas and defining a circuit configuration through the plurality of row couples.

3. The thermoelectric module of claim 2, wherein the plurality of row couples are connected in parallel between the first and second connector members.

4. The thermoelectric module of claim 2, wherein the plurality of row couples are connected in series by the first and second connector members.

5. The thermoelectric module of claim 2, wherein the plurality of row couples are connected in a combination parallel and series configuration by the first and second connector members.

6. The thermoelectric module of claim 2, wherein the conductive surface layer of at least one of the first connector member and the second connector member is patterned to provide conductive material regions separated by at least one non-conductive region, wherein the pattern defines the circuit configuration through the plurality of row couples.

7. The thermoelectric module of claim 6, wherein at least one of the first connector member and the second connector member comprises the conductive surface layer under an electrically non-conductive layer, and wherein the conductive surface layer is patterned by removing at least a portion of the conductive surface layer from the non-conductive layer to leave gaps comprising the non-conductive regions.

8. The thermoelectric module of claim 2, wherein at least one of the first connector member and the second connector member is formed using a direct bonded copper (DBC) technique.

9. The thermoelectric module of claim 1, wherein each row couple comprises a first plurality of metal connectors connecting the hot sides of adjacent thermoelectric material legs and a second plurality of metal connectors connecting the cold sides of adjacent thermoelectric material legs, wherein each of the bonding areas comprises a surface of a metal connector.

10. The thermoelectric module of claim 9, wherein at least one of the first plurality of metal connectors and the second plurality of metal connectors are formed using a direct bonded copper (DBC) technique.

11. The thermoelectric module of claim 9, wherein the first plurality of metal connectors are offset from the second plurality of metal connectors such that the thermoelectric material legs of each row couple are connected in series.

12. The thermoelectric module of claim 9, wherein the second plurality of metal connectors are not bonded to a common supporting substrate.

13. The thermoelectric module of claim 9, wherein the first plurality of metal connectors and the second plurality of metal connectors each comprise a non-conductive coating over a surface of the connector to provide electrical isolation of the row couple.

14. The thermoelectric module of claim 1, wherein a filling factor of the module is 80% or more.

15. The thermoelectric module of claim 14, wherein the filling factor of the module is 90% or more.

16. The thermoelectric module of claim 1, wherein at least one of the first connector and the second connector comprises a first connector component bonded to a first surface of each of the respective bonding areas of the plurality of row couples and at least one second connector component bonded to a second surface of one or more bonding areas of the plurality of row couples, wherein the second surface is opposite the first surface, the first connector component providing mechanical support for the plurality of row couples and the at least one second connector component providing electrical connection between the plurality of row couples.

17. The thermoelectric module of claim 16, wherein each of the second connector components comprises an electrically conductive surface layer bonded to the bonding areas and defining a circuit configuration through the plurality of row couples, and wherein the first connector component is electrically isolated from the bonding areas.

18. The thermoelectric module of claim 17, wherein at least one of the first connector component and the second connector component is formed using a direct bonded copper (DBC) technique.

19. A method of fabricating a thermoelectric module, comprising:
providing a plurality of row couples each comprising interconnected pairs of n-type and p-type thermoelectric material legs between a first bonding area and a second bonding area;
bonding a first connector to each of the first bonding areas of the plurality of row couples; and
bonding a second connector to each of the second bonding areas of the plurality of row couples, wherein the first and second connectors provide mechanical support for and electrical connection between the plurality of row couples.

20. The method of claim 19, wherein bonding each of the first and second connectors comprises bonding an electrically conductive surface layer of each of the connector members to the respective first and second bonding areas to define a circuit configuration through the plurality of row couples.

21. The method of claim 20, wherein the circuit configuration comprises a parallel circuit configuration through the plurality of row couples.

22. The method of claim 20, wherein the circuit configuration comprises a series circuit configuration through the plurality of row couples.

23. The method of claim 20, wherein the circuit configuration comprises a combination parallel and series circuit configuration through the plurality of row couples.

24. The method of claim 20, further comprising:
patterning the conductive surface layer of at least one of the first connector member and the second connector member to provide conductive material regions separated by at least one non-conductive region, wherein the pattern defines the circuit configuration through the plurality of row couples.

25. The method of claim 24, wherein at least one of the first connector member and the second connector member comprises the conductive surface layer under an electrically non-conductive layer, and wherein patterning the conductive surface layer comprises removing at least a portion of the conductive surface layer from the non-conductive layer to leave gaps comprising the non-conductive regions.

26. The method of claim 20, further comprising:
forming at least one of the first connector member and the second connector member using a direct bonded copper (DBC) technique.

27. The method of claim 19, wherein providing the plurality of row couples comprises connecting the hot sides of adjacent thermoelectric material legs with a first plurality of metal connectors and connecting the cold sides of adjacent thermoelectric material legs with a second plurality of metal connectors, wherein each of the bonding areas comprises a surface of a metal connector.

28. The method of claim 27, further comprising forming at least one of the first plurality of metal connectors and the second plurality of metal connectors using a direct bonded copper (DBC) technique.

29. The method of claim 27, wherein the first plurality of metal connectors are offset from the second plurality of metal connectors such that the thermoelectric material legs of each row couple are connected in series.

30. The method of claim 27, wherein the second plurality of metal connectors are not bonded to a common supporting substrate.

31. The method of claim 27, wherein the first plurality of metal connectors and the second plurality of metal connectors each comprise a non-conductive coating over a surface of the connector to provide electrical isolation of the row couple.

32. The method of claim 19, wherein a filling factor of the module is 80% or more.

33. The method of claim 32, wherein the filling factor of the module is 90% or more.

34. The method of claim 19, wherein bonding at least one of the first connector and the second connector comprises bonding a first connector component to a first surface of each of the respective bonding areas of the plurality of row couples and bonding at least one second connector component to a second surface of one or more bonding areas of the plurality of row couples, wherein the second surface is opposite the first surface, the first connector component providing mechanical support for the plurality of row couples and the at least one second connector component providing electrical connection between the plurality of row couples.

35. The method of claim 34, wherein each of the second connector components comprises an electrically conductive surface layer bonded to the bonding areas and defining a circuit configuration through the plurality of row couples, and wherein the first connector component is electrically isolated from the bonding areas.

36. The method of claim 35, wherein at least one of the first connector component and the second connector component is formed using a direct bonded copper (DBC) technique.
